(19) United States
(12) Patent Application Publication
(10) Pub. No.: US 2025/0068047 A1
(43) Pub. Date: Feb. 27, 2025

(54) OPTICAL MACHINE MODULE AND PROJECTOR DEVICE

(71) Applicant: Qisda Corporation, Taoyuan City (TW)

(72) Inventors: Ko-Szu Yu, Taoyuan City (TW); Chien Yu Shih, Taoyuan City (TW)

(73) Assignee: Qisda Corporation, Taoyuan City (TW)

(21) Appl. No.: 18/796,244

(22) Filed: Aug. 6, 2024

(30) Foreign Application Priority Data
Aug. 21, 2023 (CN) 202311050878.1

(51) Int. Cl. G03B 21/16; G03B 21/14; G03B 21/20

(52) U.S. Cl. CPC G03B 21/16; G03B 21/145; G03B 21/2033

(57) ABSTRACT

An optical machine module includes an optical machine housing, a radiator cover, a light source, and an internal radiator. The radiator cover covers the optical machine housing to jointly form an inner space, and the radiator cover includes a cover inner surface facing the inner space. The light source is disposed on the cover inner surface. The internal radiator is located beside the cover inner surface and close to the light source, and the internal radiator is thermally coupled to the radiator cover.

### CROSS-REFERENCE TO RELATED APPLICATION

This application claims the priority benefit of China application serial no. 202311050878.1, filed on Aug. 21, 2023. The entirety of the above-mentioned patent application is hereby incorporated by reference herein and made a part of this specification.

### BACKGROUND

### Technical Field

The disclosure relates to an optical machine module and a projector device, and in particular to an optical machine module and a projector device with proper heat dissipation effect.

### Description of Related Art

Currently, the size of the projector device is getting smaller and smaller, and the optical machine module of the projector device may generate high heat during operation. How to improve the heat dissipation effect of the optical machine module is the direction of research in this field.

### SUMMARY

The disclosure provides an optical machine module, which has an internal radiator and can improve the heat dissipation effect in a limited space.

The disclosure provides a projector device, including the optical machine module.

An optical machine module of the disclosure includes an optical machine housing, a radiator cover, a light source, and an internal radiator. The radiator cover covers the optical machine housing to jointly form an inner space. The radiator cover includes a cover inner surface facing the inner space. The light source is disposed on the cover inner surface. The internal radiator is located next to the cover inner surface of the cover and close to the light source, and the internal radiator is thermally coupled to the radiator cover.

In an embodiment of the disclosure, the optical machine module further includes an insulating board, wherein the insulating board includes an insulating board outer surface, and the radiator cover is disposed on the insulating board outer surface to be fixed to the optical machine housing through the insulating board.

In an embodiment of the disclosure, the insulating board includes a first hole and a second hole adjacent to each other, the light source is located on the first hole, and the internal radiator is located on the second hole.

In an embodiment of the disclosure, one of the cover inner surface of the radiator cover and the insulating board outer surface of the insulating board includes a first annular protruding rib, and another includes a first annular groove, a first sealing ring is disposed in the first annular groove, the first annular protruding rib extends into the first annular groove and presses the first sealing ring, and the first annular protruding rib or the first annular groove of the insulating board surrounds the first hole and the second hole.

In an embodiment of the disclosure, one of an optical machine upper surface of the optical machine housing and an insulating board inner surface includes a second annular protruding rib, and another includes a second annular groove, a second sealing ring is disposed in the second annular groove, and the second annular protruding rib extends into the second annular groove and presses the second sealing ring.

In an embodiment of the disclosure, the insulating board includes a wiring structure located on the insulating board outer surface.

In an embodiment of the disclosure, the insulating board includes an insulating board inner surface and a plurality of structural strengthening ribs located on the insulating board inner surface.

In an embodiment of the disclosure, the optical machine module further includes an external radiator. The radiator cover includes a cover outer surface relative to the cover inner surface, and the external radiator is disposed on the cover outer surface.

In an embodiment of the disclosure, the external radiator includes a fan, a fin, a cooler, or a water cooling radiator, and the internal radiator includes a fan, a fin, or a cooler.

In an embodiment of the disclosure, the light source is a laser light source or a light-emitting diode light source.

A projector device of the disclosure includes the optical machine module, an imaging module, and a lens module. The optical machine module is used to provide an illumination beam. The imaging module is located on an optical path of the illumination beam to convert the illumination beam into an image beam. The lens module is located on an optical path of the image beam to project the image beam out of the projector device.

Based on the above, in the optical machine module of the projector device of the disclosure, the radiator cover covers the optical machine housing. The light source is disposed on the cover inner surface of the radiator cover. The internal radiator is disposed next to the cover inner surface and thermally coupled to the radiator cover. The optical machine module of the disclosure disposes the internal radiator in the inner space, and provides proper space utilization, so that the optical machine module may maintain smaller overall volume. In addition, the light source and the internal radiator are both located next to the cover inner surface and on the same side of the radiator cover. Such configuration allows the heat energy emitted by the light source to be properly transmitted to the internal radiator through the radiator cover, thereby providing proper heat dissipation effect for the optical machine module.

### BRIEF DESCRIPTION OF THE DRAWINGS

FIG. 1 is a schematic diagram of the appearance of an optical machine module according to an embodiment of the disclosure.

FIG. 2 is a schematic diagram of hiding the external radiator and the heat pipe of FIG. 1.

FIG. 3 is a schematic diagram of moving a radiator cover, a light source, an internal radiator, and an insulating board of FIG. 2 upward.

FIG. 4 is a schematic diagram of FIG. 3 from another perspective.

FIG. 5 is a schematic diagram of hiding an optical machine housing of FIG. 4 and moving the internal radiator downward.

FIG. 6 is an exploded schematic view of hiding the internal radiator of FIG. 5.

FIG. 7 is a schematic diagram of the insulating board of the optical machine module of FIG. 1.

FIG. 8 is a schematic diagram of a projector device according to an embodiment of the disclosure.

### DESCRIPTION OF THE EMBODIMENTS

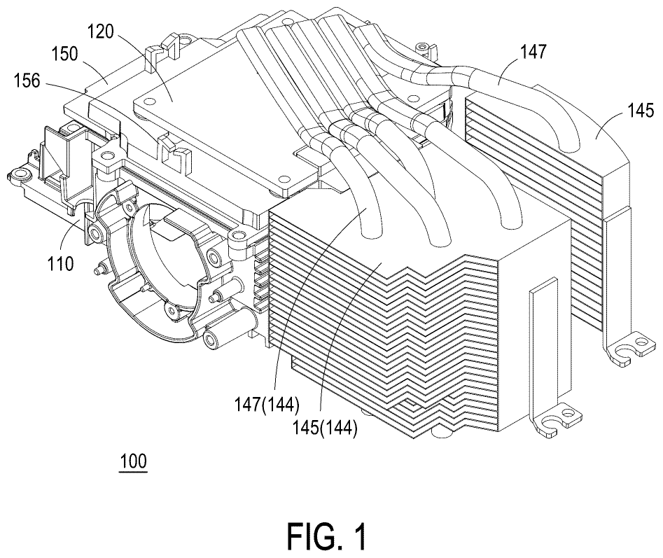

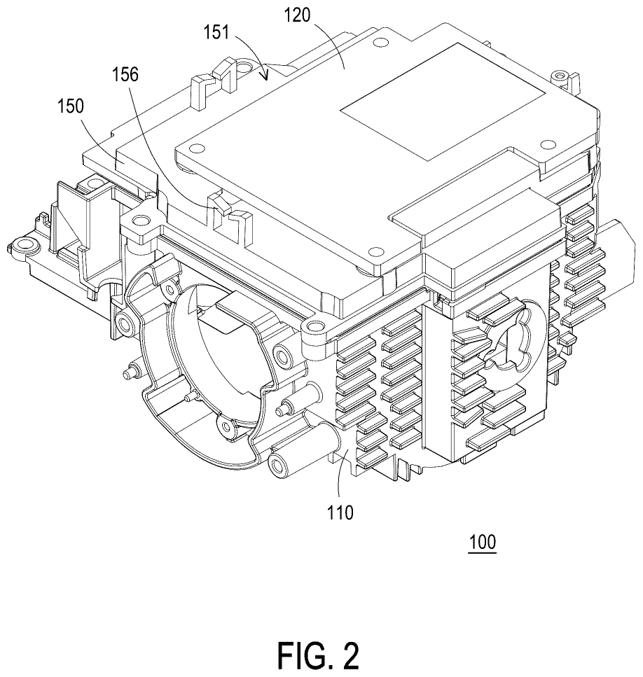

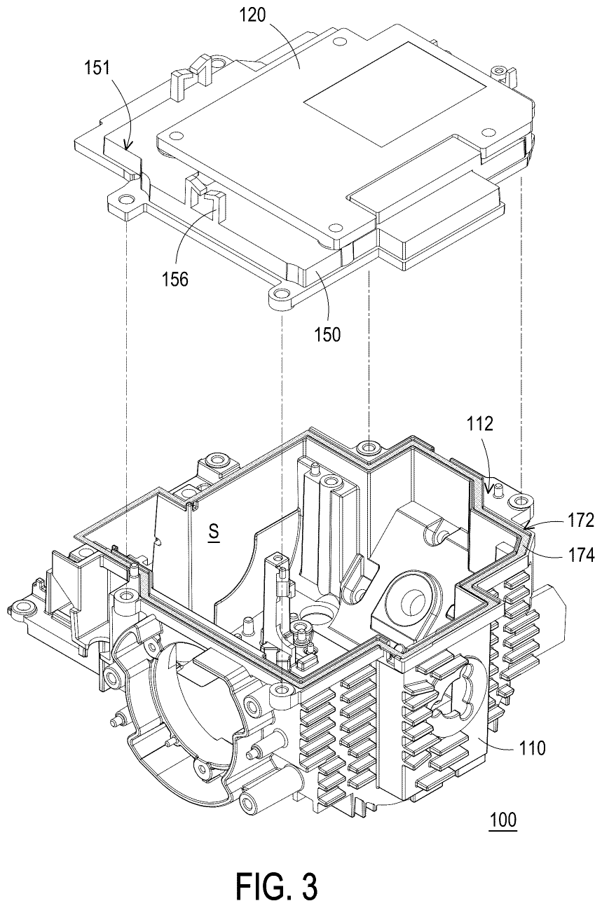

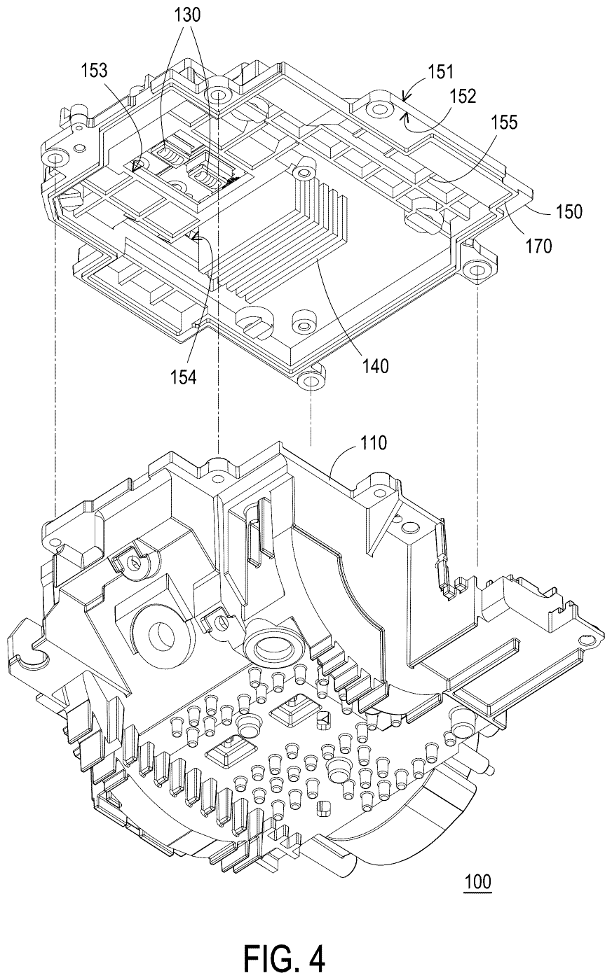

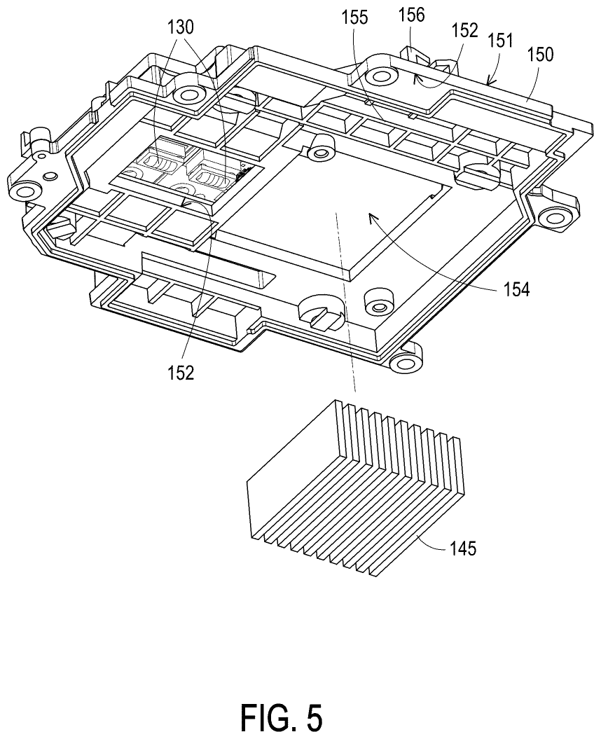

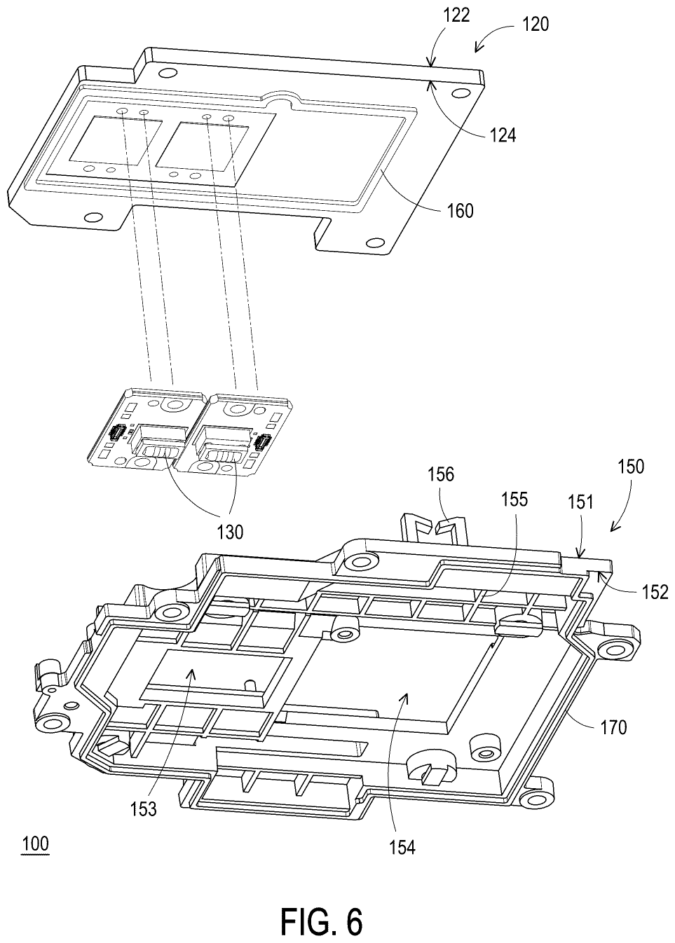

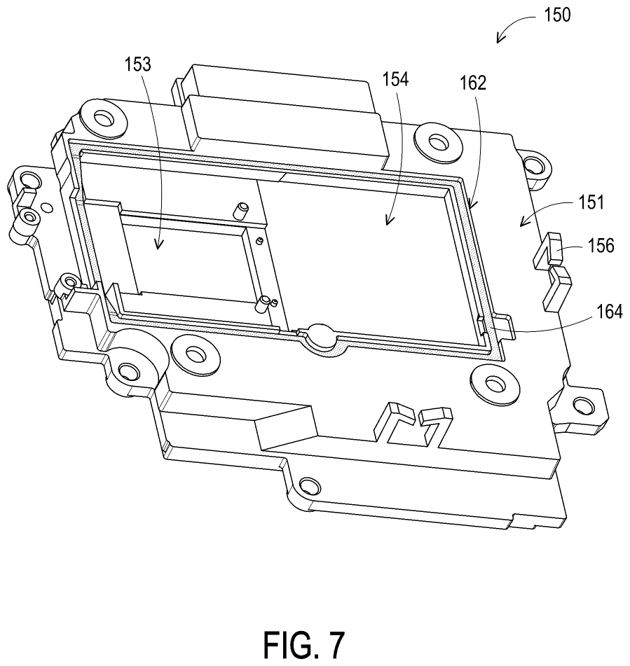

FIG. 1 is a schematic diagram of the appearance of an optical machine module according to an embodiment of the disclosure. FIG. 2 is a schematic diagram of hiding an external radiator and a heat pipe of FIG. 1. FIG. 3 is a schematic diagram of moving a radiator cover, a light source, an internal radiator, and an insulating board of FIG. 2 upward. FIG. 4 is a schematic diagram of FIG. 3 from another perspective. FIG. 5 is a schematic diagram of hiding the optical machine housing in FIG. 4 and moving the internal radiator downward. FIG. 6 is an exploded schematic view of hiding the internal radiator of FIG. 5. FIG. 7 is a schematic diagram of the insulating board of the optical machine module of FIG. 1.

Referring to FIGS. 1 to 7, an optical machine module 100 of this embodiment includes an optical machine housing 110, a radiator cover 120, a light source 130 (FIG. 4), and an internal radiator 140 (FIG. 4). The radiator cover 120 covers the optical machine housing 110 to jointly form an inner space S (FIG. 3).

As shown in FIG. 6, the radiator cover 120 includes a cover inner surface 124 facing the inner space S (FIG. 3), and the light source 130 is disposed on the cover inner surface 124. The light source 130 is a laser light source 130 or a light-emitting diode light source 130, but the type of the light source 130 is not limited thereto.

As shown in FIGS. 5 and 6, the internal radiator 140 (FIG. 5) is located next to the cover inner surface 124 and close to the light source 130. The internal radiator 140 is thermally coupled to the radiator cover 120 (FIG. 6). In this embodiment, the internal radiator 140 includes a fin, but in other embodiments, the internal radiator 140 may also include a fan, a fin, or a cooler, and the type of the internal radiator 140 is not limited thereto.

In the optical machine module 100 of this embodiment, the internal radiator 140 is disposed next to the cover inner surface 124 and located on the inner space S (FIG. 3). Therefore, the inner space S of the optical machine module 100 may be properly utilized and may improve a heat dissipation effect of the optical machine module 100. In addition, in this embodiment, the light source 130 and the internal radiator 140 are both located next to the cover inner surface 124 and on the same side of the radiator cover 120. Such configuration allows the heat energy emitted by the light source 130 to be properly transmitted to the internal radiator 140 through the radiator cover 120, thereby providing a proper heat dissipation effect for the optical machine module 100.

It is worth mentioning that in this embodiment, in response to the material of the optical machine housing 110 being metal and the voltage input to the light source 130 being relatively high (for example, more than 60 volts), in order to increase safety, the optical machine module 100 may further optionally include an insulating board 150. The insulating board 150 is disposed between the light source 130 and the optical machine housing 110 to properly isolate electrical energy. In this embodiment, the material of the insulating board 150 is, for example, plastic, but it is not limited thereto.

As shown in FIG. 6, the insulating board 150 includes an insulating board outer surface 151. The radiator cover 120 is disposed on the insulating board outer surface 151 to be fixed to the optical machine housing 110 through the insulating board 150.

The insulation board 150 includes a first hole 153 and a second hole 154 adjacent to each other. The light source 130 is located on the first hole 153, and the internal radiator 140 (FIG. 4) is located on the second hole 154. To be precise, in this embodiment, the light source 130 passes through the first hole 153 and is fixed on the radiator cover 120, and the internal radiator 140 passes through the second hole 154 and is fixed on the radiator cover 120.

Of course, in other embodiments, the light source 130 and/or the internal radiator 140 may also be fixed to the insulating board 150 and contact with the radiator cover 120. The configuration relationship of the light source 130, the internal radiator 140, the radiator cover 120, and the insulating board 150 is not limited thereto.

In addition, in this embodiment, the optical machine module 100 is designed to achieve a dust-proof effect to prevent dust from entering the inner space S from the gaps between the components (FIG. 3). One of the cover inner surface 124 of the radiator cover 120 and the insulating board outer surface 151 of the insulating board 150 includes a first annular protruding rib 160, and another one includes a first annular groove 162.

Specifically, as shown in FIG. 6, the cover inner surface 124 of the radiator cover 120 includes the first annular protruding rib 160. As shown in FIG. 7, the insulating board outer surface 151 of the insulating board 150 includes the first annular groove 162. The first annular groove 162 of the insulating board 150 surrounds the first hole 153 and the second hole 154. A first sealing ring 164 is disposed in the first annular groove 162.

When the radiator cover 120 is assembled to the insulating board 150, the first annular protruding rib 160 extends into the first annular groove 162 and presses the first sealing ring 164 to provide sealing between the radiator cover 120 and the insulating board 150.

In addition, as shown in FIGS. 3 and 4, one of an optical machine upper surface 112 of the optical machine housing 110 and an insulating board inner surface 152 of the insulating board 150 includes a second annular protruding rib 170 (FIG. 3), and another one includes a second annular groove 172 (FIG. 4).

Specifically, the insulating board inner surface 152 of the insulating board 150 includes the second annular protruding rib 170. The optical machine upper surface 112 of the optical machine housing 110 includes the second annular groove 172. A second sealing ring 174 (FIG. 4) is disposed in the second annular groove 172.

When the insulating board 150 is assembled on the optical machine housing 110, the second annular protruding rib 170 extends into the second annular groove 172 and presses the second sealing ring 174 to provide sealing between the insulating board 150 and the optical machine housing 110.

In addition, in this embodiment, the insulation board 150 further includes a wiring structure 156 located on the insulting board outer surface 151. The wiring structure 156 may be used to fix wires (not shown) outside the optical machine housing 110. For example, in an embodiment, in response to an external radiator 145 being a fan, the wiring structure 156 may be used to fix the wires of the external radiator 145. In another embodiment, the wiring structure 156 may be used to fix the wires of the light source 130 or other electronic components (not shown) in the optical machine housing 110. In this way, the wires around the optical machine module 100 of this embodiment may be kept neat and orderly to avoid messy wires.

Furthermore, as may be seen from FIG. 5, in this embodiment, the insulating board 150 includes the insulating board inner surface 152 and multiple structural strengthening ribs 155 located on the insulating board inner surface 152. The structural strengthening ribs 155 are, for example, staggered to form multiple frame shapes to enhance a structural strength of the insulating board 150 in different directions, but the arrangement of the structural strengthening ribs 155 is not limited thereto.

In addition, as shown in FIG. 1, in this embodiment, the optical machine module 100 further includes an external radiator 144. The radiator cover 120 includes a cover outer surface 122 relative to the cover inner surface 124. The external radiator 144 is disposed on the cover outer surface 122.

Specifically, in this embodiment, the external radiator 144 includes a combination of a fin 145 and a heat pipe 147. The heat pipe 147 contacts the radiator cover 120 and penetrates through the fin 145. Therefore, the fin 145 is thermally coupled to the radiator cover 120 through the heat pipe 147. In other embodiments, the external radiator 144 may also include a fan, a cooler, or a water cooling radiator, and the type of the external radiator 144 is not limited thereto.

In this embodiment, the heat emitted by the light source 130 of the optical machine module 100 may be synchronously transmitted to the internal radiator 140 and the external radiator 144 through the radiator cover 120, and may perform heat dissipation through the internal radiator 140 and external radiator 144 at the same time. In addition, the internal radiator 140 is disposed in the inner space S, so that the optical machine module 100 may still maintain a small overall size and have the heat dissipation effect of multiple radiators.

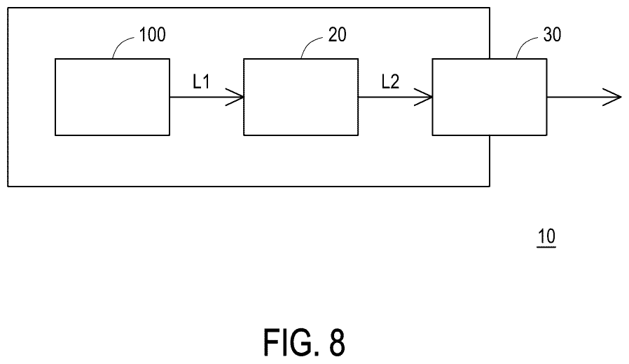

FIG. 8 is a schematic diagram of a projector device according to an embodiment of the disclosure Referring to FIG. 8, a projector device 10 of this embodiment includes an optical machine module 100, an imaging module 20, and a lens module 30. The optical machine module 100 is, for example, the optical machine module 100 in FIG. 1, but is not limited thereto. As long as being the optical machine module which disposes the internal radiator 140 in the inner space S, have the light source 130 and the internal radiator 140 locate next to the cover inner surface 124, and is located on the same side of the radiator cover 120, a proper space utilization and a proper heat dissipation effect for the optical machine module are provided.

The optical machine module 100 is used to provide an illumination beam L1. The illumination beam L1 leaves the optical machine module 100 along a required optical path. The imaging module 20 is located on an optical path of the illumination beam L1 to convert the illumination beam L1 into an image beam L2. The imaging module 20 is, for example, a digital micromirror device (DMD), but the type of the imaging module 20 is not limited thereto. The lens module 30 is located on an optical path of the image beam L2 to project the image beam L2 out of the projector device 10. The projector device 10 of this embodiment has the proper heat dissipation effect through the optical machine module 100, thereby further improving the heat dissipation performance.

To sum up, in the optical machine module of the projector device of the disclosure, the radiator cover covers the optical machine housing. The light source is disposed on the cover inner surface of the radiator cover. The internal radiator is disposed next to the cover inner surface and thermally coupled to the radiator cover. The optical machine module of the disclosure disposes the internal radiator in the inner space, and provides proper space utilization, so that the optical machine module may maintain the smaller overall volume. In an embodiment, even if the optical machine module is provided with an external radiator, the optical machine module of the disclosure still has a smaller overall size compared with disposing all the radiators outside the optical machine module. In addition, the light source and the internal radiator are both located next to the cover inner surface and on the same side of the radiator cover. Such configuration allows the heat energy emitted by the light source to be properly transmitted to the internal radiator through the radiator cover, thereby providing proper heat dissipation effect for the optical machine module.

What is claimed is:

1. An optical machine module, comprising:
an optical machine housing;
a radiator cover, covering the optical machine housing to jointly form an inner space, wherein the radiator cover comprises a cover inner surface facing the inner space;
a light source, disposed on the cover inner surface; and
an internal radiator, located next to the cover inner surface and close to the light source, wherein the internal radiator is thermally coupled to the radiator cover.

2. The optical machine module according to claim 1, further comprising an insulating board, wherein the insulating board comprises an insulating board outer surface, and the radiator cover is disposed on the insulating board outer surface to be fixed to the optical machine housing through the insulating board.

3. The optical machine module according to claim 2, wherein the insulating board comprises a first hole and a second hole adjacent to each other, the light source is located on the first hole, and the internal radiator is located on the second hole.

4. The optical machine module according to claim 3, wherein one of the cover inner surface of the radiator cover and the insulating board outer surface of the insulating board comprises a first annular protruding rib, another one comprises a first annular groove, a first sealing ring is disposed in the first annular groove, the first annular protruding rib extends into the first annular groove and presses the first sealing ring, and the first annular protruding rib or the first annular groove of the insulating board surrounds the first hole and the second hole.

5. The optical machine module according to claim 2, wherein one of an optical machine upper surface of the optical machine housing and an insulating board inner surface of the insulating board comprises a second annular protruding rib, and another one comprises a second annular groove, a second sealing ring is disposed in the second annular groove, and the second annular protruding rib extends into the second annular groove and presses the second sealing ring.

6. The optical machine module according to claim 2, wherein the insulating board comprises a wiring structure located on the insulating board outer surface.

7. The optical machine module according to claim 2, wherein the insulating board comprises an insulating board inner surface and a plurality of structural strengthening ribs located on the insulating board inner surface.

8. The optical machine module according to claim 1, further comprising an external radiator, wherein the radiator cover comprises a cover outer surface relative to the cover inner surface, and the external radiator is disposed on the cover outer surface.

9. The optical machine module according to claim 8, wherein the external radiator comprises a fan, a fin, a cooler, or a water cooling radiator, and the internal radiator comprises a fan, a fin, or a cooler.

10. The optical machine module according to claim 1, wherein the light source is a laser light source or a light-emitting diode light source.

11. A projector device, comprising:
an optical machine module, configured to provide an illumination beam, the optical machine module comprising:
an optical machine housing;
a radiator cover, covering the optical machine housing to jointly form an inner space, wherein the radiator cover comprises a cover inner surface facing the inner space;
a light source, disposed on the cover inner surface; and
an internal radiator, located next to the cover inner surface and close to the light source, wherein the internal radiator is thermally coupled to the radiator cover;
an imaging module, located on an optical path of the illumination beam to convert the illumination beam into an image beam; and
a lens module, located on an optical path of the image beam to project the image beam out of the projector device.

12. The projector device according to claim 11, further comprising an insulating board, wherein the insulating board comprises an insulating board outer surface, and the radiator cover is disposed on the insulating board outer surface to be fixed to the optical machine housing through the insulating board.

13. The projector device according to claim 12, wherein the insulating board comprises a first hole and a second hole adjacent to each other, the light source is located on the first hole, and the internal radiator is located on the second hole.

14. The projector device according to claim 13, wherein one of the cover inner surface of the radiator cover and the insulating board outer surface of the insulating board comprises a first annular protruding rib, another one comprises a first annular groove, a first sealing ring is disposed in the first annular groove, the first annular protruding rib extends into the first annular groove and presses the first sealing ring, and the first annular protruding rib or the first annular groove of the insulating board surrounds the first hole and the second hole.

15. The projector device according to claim 12, wherein one of an optical machine upper surface of the optical machine housing and an insulating board inner surface of the insulating board comprises a second annular protruding rib, and another one comprises a second annular groove, a second sealing ring is disposed in the second annular groove, and the second annular protruding rib extends into the second annular groove and presses the second sealing ring.

16. The projector device according to claim 12, wherein the insulating board comprises a wiring structure located on the insulating board outer surface.

17. The projector device according to claim 12, wherein the insulating board comprises an insulating board inner surface and a plurality of structural strengthening ribs located on the insulating board inner surface.

18. The projector device according to claim 11, further comprising an external radiator, wherein the radiator cover comprises a cover outer surface relative to the cover inner surface, and the external radiator is disposed on the cover outer surface.

19. The projector device according to claim 18, wherein the external radiator comprises a fan, a fin, a cooler, or a water cooling radiator, and the internal radiator comprises a fan, a fin, or a cooler.

20. The projector device according to claim 11, wherein the light source is a laser light source or a light-emitting diode light source.
